(19) United States
(12) Patent Application Publication
(10) Pub. No.: US 2023/0178609 A1
(43) Pub. Date: Jun. 8, 2023

(54) MOSFET FOR SUPPRESSING GIDL, METHOD FOR MANUFACTURING MOSFET, AND ELECTRONIC APPARATUS INCLUDING MOSFET

(71) Applicant: INSTITUTE OF MICROELECTRONICS, CHINESE ACADEMY OF SCIENCES, Beijing (CN)

(72) Inventor: Huilong ZHU, Poughkeepsie, NY (US)

(21) Appl. No.: 18/051,434

(22) Filed: Oct. 31, 2022

(30) Foreign Application Priority Data
Nov. 1, 2021 (CN) 202111285529.9

(51) Int. Cl. H01L 29/10; H01L 29/04; H01L 29/08; H01L 29/66

(52) U.S. Cl. CPC H01L 29/105; H01L 29/04; H01L 29/0847; H01L 29/66666

(57) ABSTRACT

A metal oxide semiconductor field effect transistor (MOSFET), a method for manufacturing MOSFET, and an electronic apparatus including MOSFET are disclosed. The MOSFET include: a vertical channel portion on a substrate; source/drain portions respectively located at upper and lower ends of the channel portion with respect to the substrate; and a gate stack opposite to the channel portion. The channel portion has doping concentration distribution, so that when the MOSFET is an n-type MOSFET (nMOSFET), a threshold voltage of a first portion of the channel portion close to one of the source/drain portions is lower than a threshold voltage of a second portion adjacent to the first portion; or when the MOSFET is a p-type MOSFET (pMOSFET), a threshold voltage of a first portion in the channel portion close to one of the source/drain portions is higher than a threshold voltage of a second portion adjacent to the first portion.

### CROSS-REFERENCE TO RELATED APPLICATION

This application claims the priority of Chinese Patent Application No. 202111285529.9 filed on Nov. 1, 2021 in the China National Intellectual Property Administration, the content of which is incorporated herein by reference in entirety.

### TECHNICAL FIELD

The present disclosure relates to a field of semiconductors, and in particular, to a metal oxide semiconductor field effect transistor (MOSFET) capable of suppressing a gate induced drain leakage (GIDL), a method for manufacturing a MOSFET, and an electronic apparatus including the MOSFET.

### BACKGROUND

With a continuous miniaturization of a metal oxide semiconductor field effect transistor (MOSFET), various different configurations have been proposed, such as a Fin Field Effect Transistor (FinFET), a Multi-Bridge Channel Field Effect Transistor (MBCFET), etc. However, a space for an improvement of these devices in terms of increasing an integration density and enhancing a device performance due to a structural limitation still may not meet requirements.

In addition, it is difficult to reduce a gate induced drain leakage (GIDL). For example, in order to reduce a leakage current between a source and a drain of an n-type MOSFET (nMOSFET), a negative bias voltage Vgs (<0) may be applied between a gate and a source. However, if a magnitude (IVgsI) of the bias voltage is too large, the GIDL may occur. Therefore, the GIDL becomes a limiting factor in reducing a leakage.

### SUMMARY

In view of this, an object of the present disclosure is, at least in part, to provide a metal oxide semiconductor field effect transistor (MOSFET) capable of suppressing a gate induced drain leakage (GIDL), a method for manufacturing a MOSFET, and an electronic apparatus including the MOSFET.

According to an aspect of the present disclosure, there is provided a MOSFET, including: a vertical channel portion on a substrate; source/drain portions respectively located at upper and lower ends of the channel portion with respect to the substrate; and a gate stack opposite to the channel portion, wherein the channel portion has a doping concentration distribution, so that when the MOSFET is an n-type MOSFET (nMOSFET), a threshold voltage of a first portion of the channel portion close to one of the source/drain portions is lower than a threshold voltage of a second portion adjacent to the first portion; or when the MOSFET is a p-type MOSFET (pMOSFET), a threshold voltage of a first portion of the channel portion close to one of the source/drain portions is higher than a threshold voltage of a second portion adjacent to the first portion.

According to another aspect of the present disclosure, there is provided a method for manufacturing a MOSFET, including: providing a stack of a first material layer, a second material layer and a third material layer on a substrate, wherein the second material layer includes a first sublayer and a second sublayer that is highly doped with respect to the first sublayer, and the stack has first and second sides opposite to each other in a first direction and third and fourth sides opposite to each other in a second direction intersecting the first direction; recessing, on the third and fourth sides, a sidewall of the second material layer in the second direction with respect to sidewalls of the first material layer and the third material layer, so as to define a first recessed portion; forming a first position maintaining layer in the first recessed portion; recessing, on the first and second sides, the sidewall of the second material layer in the first direction with respect to the sidewalls of the first material layer and the third material layer, so as to define a second recessed portion; forming a channel layer in the second recessed portion; forming a second position maintaining layer in the second recessed portion with the channel layer formed; driving a dopant in the second sublayer into the channel layer in the first direction; forming source/drain portions in the first material layer and the third material layer; forming a strip-shaped opening extending in the second direction in the stack, so as to divide the stack into two portions respectively located on the first and second sides; replacing the second material layer with a third position maintaining layer through the opening; forming an isolation layer on the substrate, wherein a top surface of the isolation layer is not lower than a top surface of the first material layer and not higher than a bottom surface of the third material layer; removing the second position maintaining layer and the third position maintaining layer; and forming a gate stack on the isolation layer, wherein the gate stack has a portion embedded in a space left by a removal of the second position maintaining layer and the third position maintaining layer.

According to another aspect of the present disclosure, there is provided an electronic apparatus, including the above-mentioned MOSFET.

According to embodiments of the present disclosure, a MOSFET having a non-uniform doping in a channel portion is proposed, which may suppress a GIDL.

### BRIEF DESCRIPTION OF THE DRAWINGS

The above and other objectives, features, and advantages of the present disclosure will be clearer through the following descriptions of embodiments of the present disclosure with reference to the drawings, in which:

FIG. 1 to FIG. 22 schematically show some stages in a process of manufacturing a metal oxide semiconductor field effect transistor (MOSFET) according to an embodiment of the present disclosure;

FIGS. 23(a) and 23(b) respectively show an energy band diagram of an n-type MOSFET (nMOSFET) according to a comparative example and an energy band diagram of an nMOSFET according to an embodiment of the present disclosure;

FIG. 24 and FIG. 25 schematically show some stages in a process of manufacturing a MOSFET according to another embodiment of the present disclosure;

FIG. 26 shows an energy band diagram of an nMOSFET according to another embodiment of the present disclosure.

In the drawings:

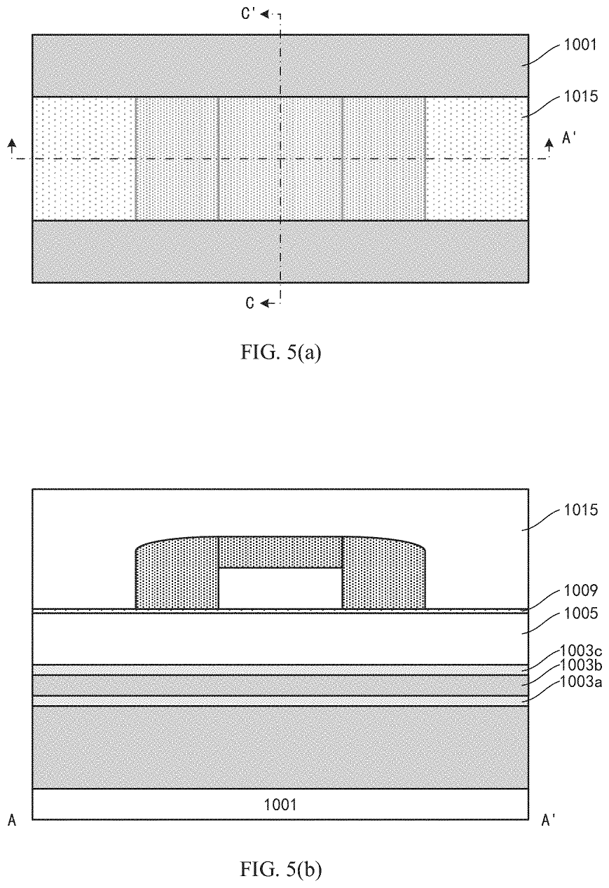

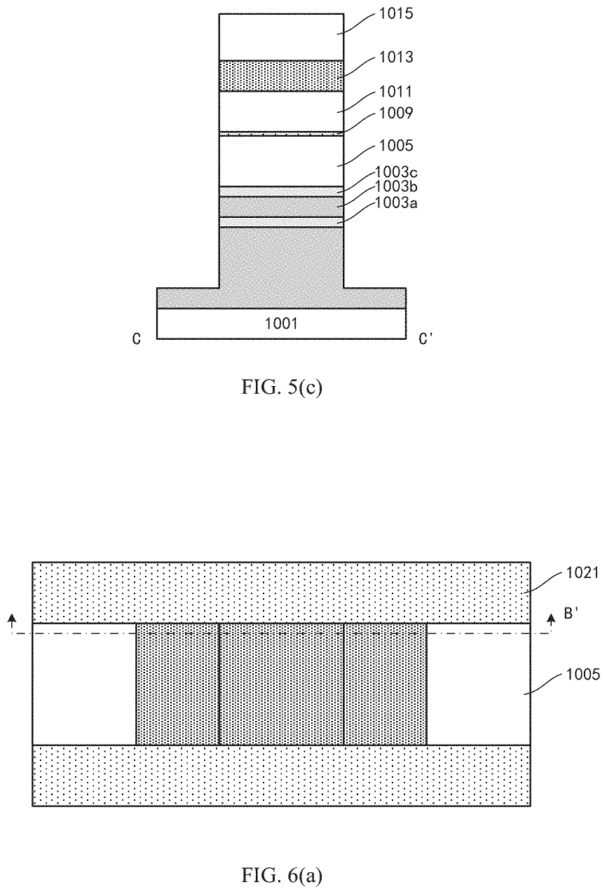

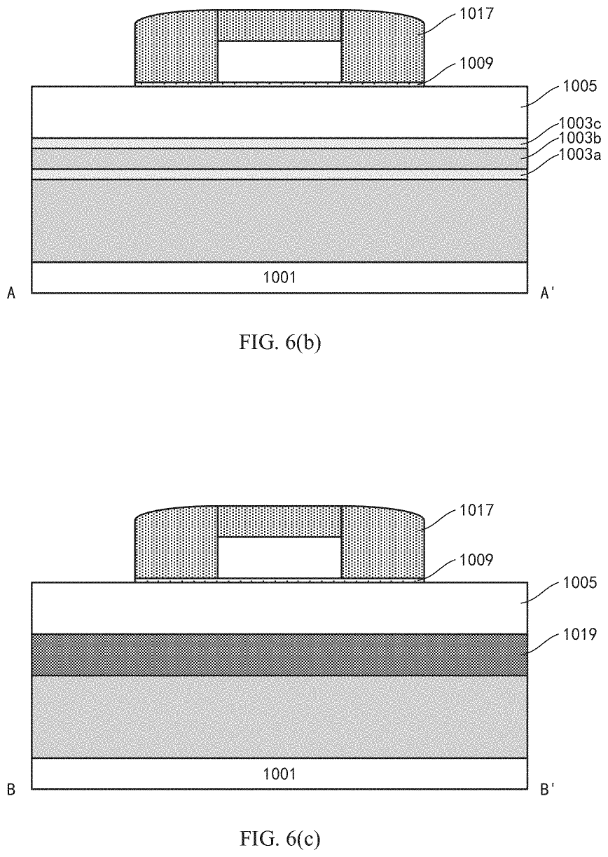

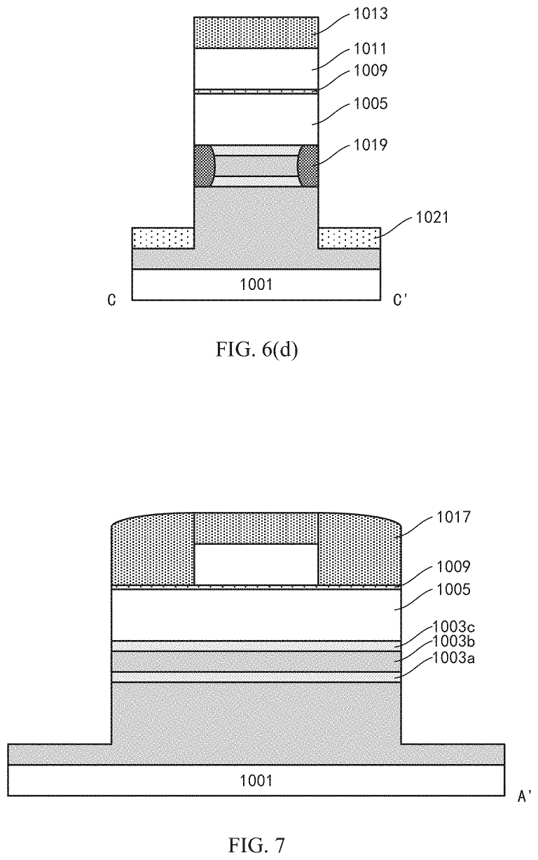

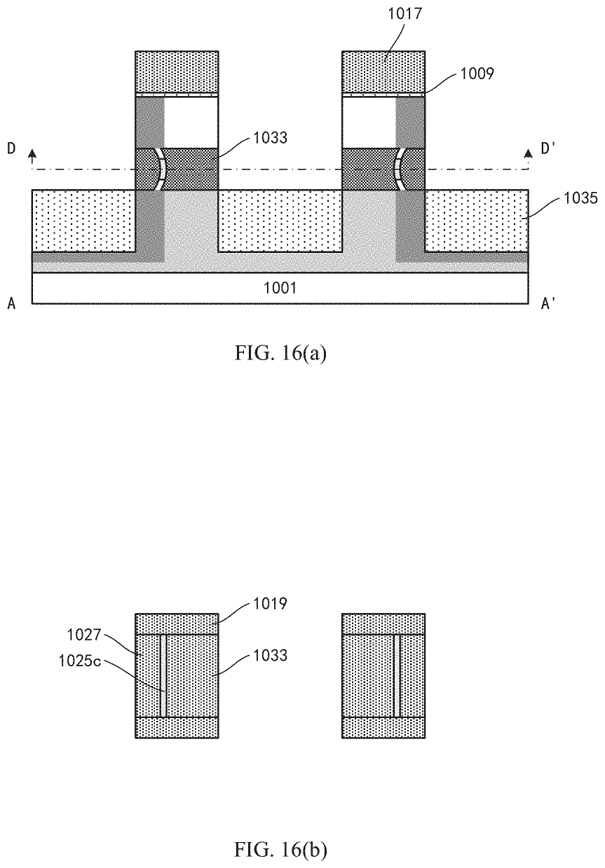

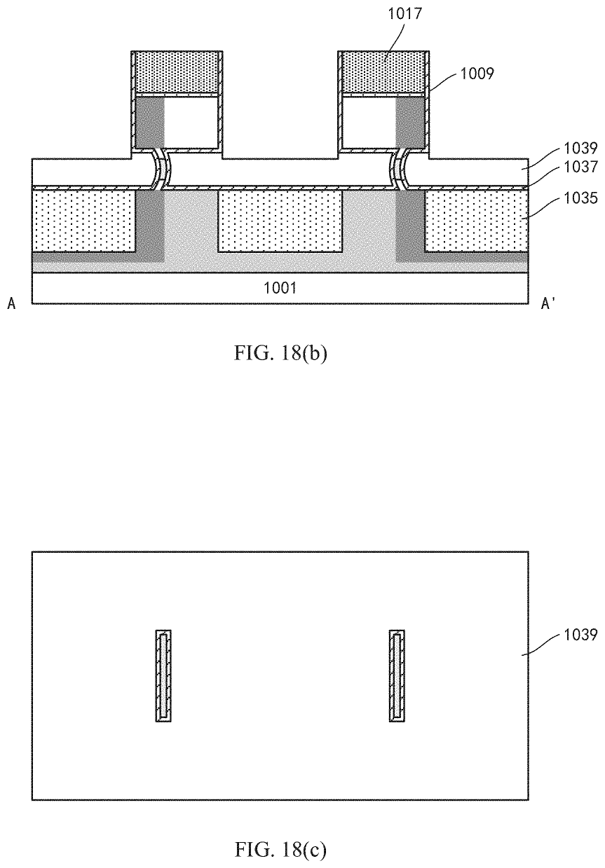

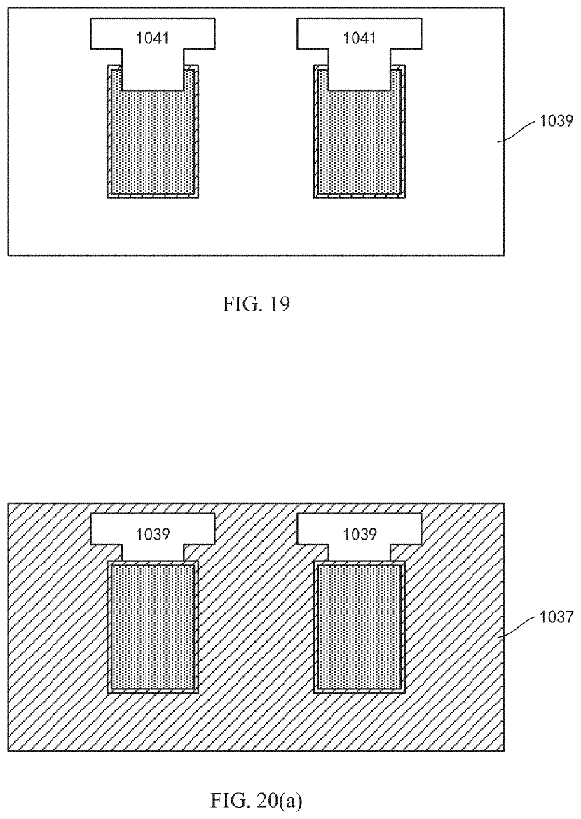

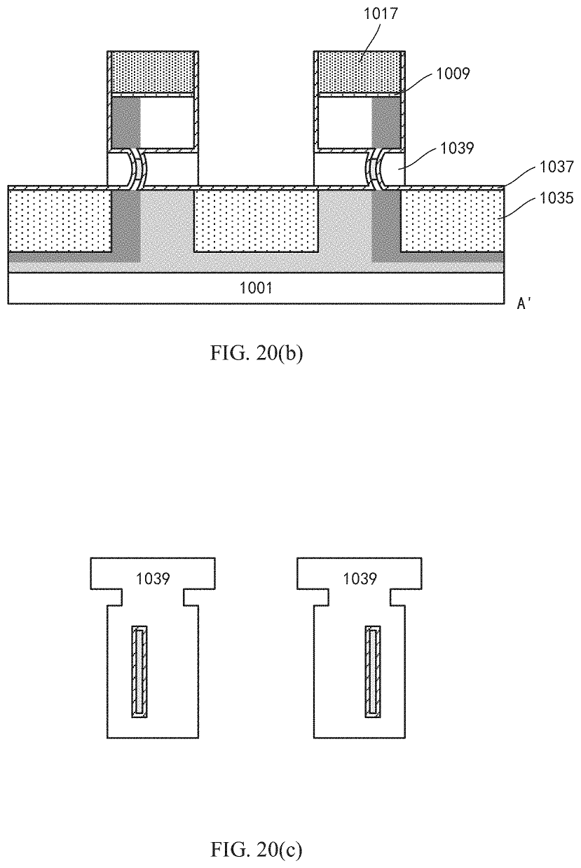

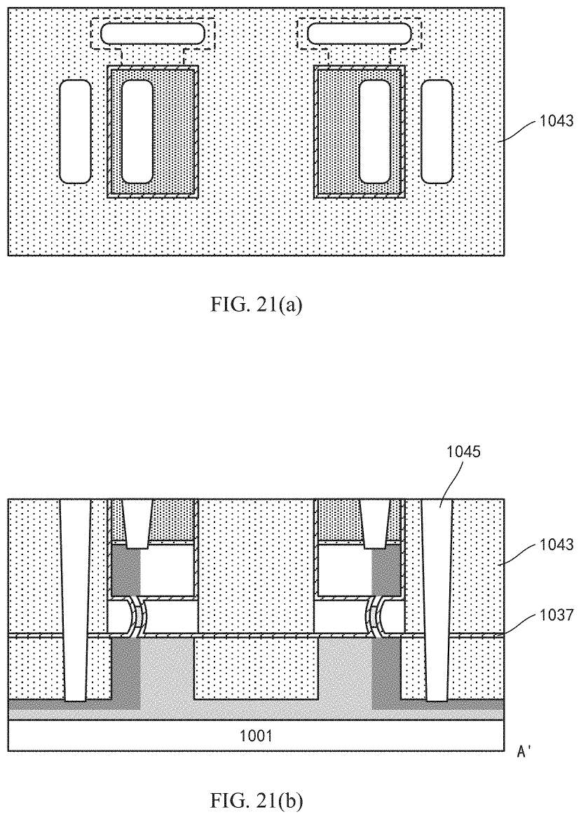

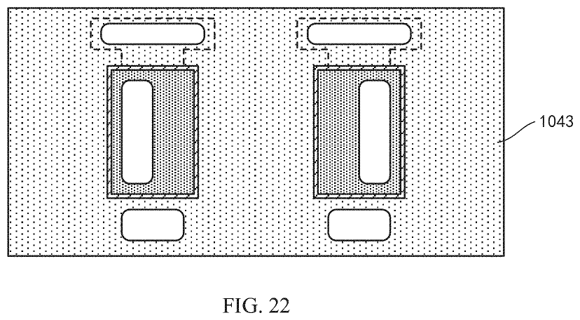

FIG. 5(a), FIG. 6(a), FIG. 18(a), FIG. 19, FIG. 20(a), FIG. 21(a), and FIG. 22 are top views, in which FIG. 5(a) shows positions of line AA′ and line CC′, FIG. 6(a) shows a position of line BB′, and FIG. 16(a) shows a position of line DD′;

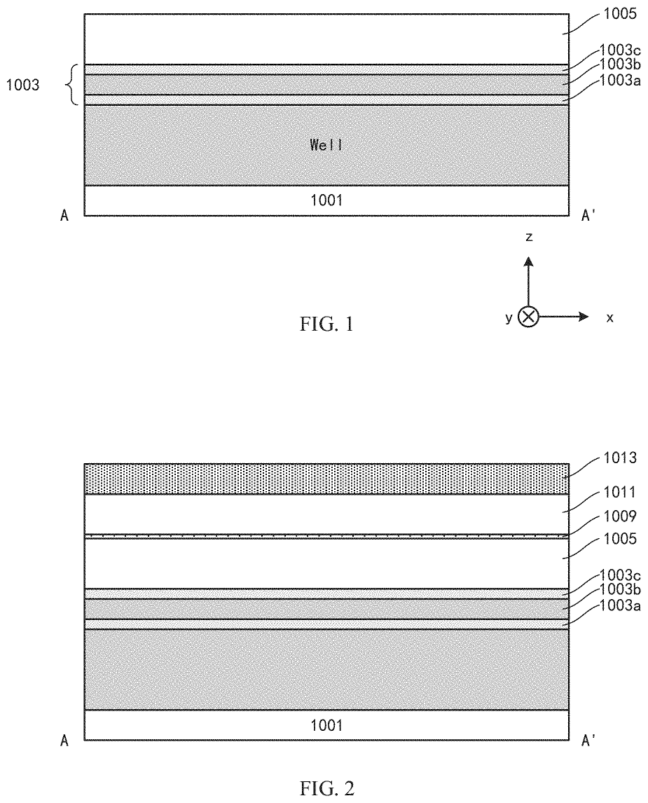

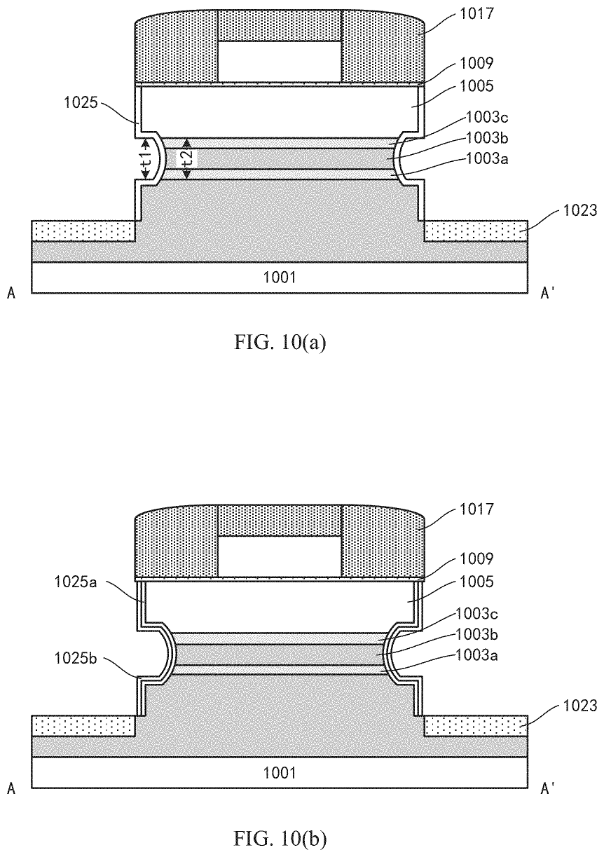

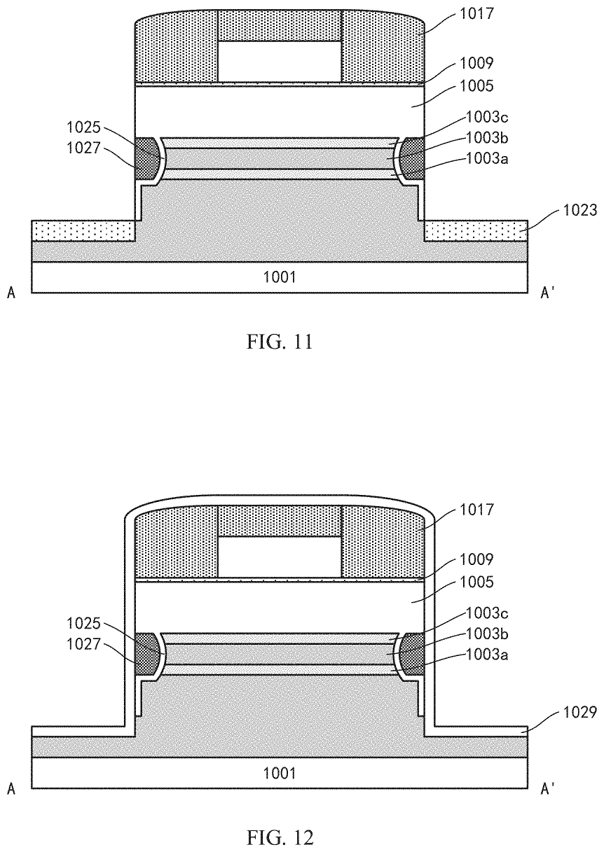

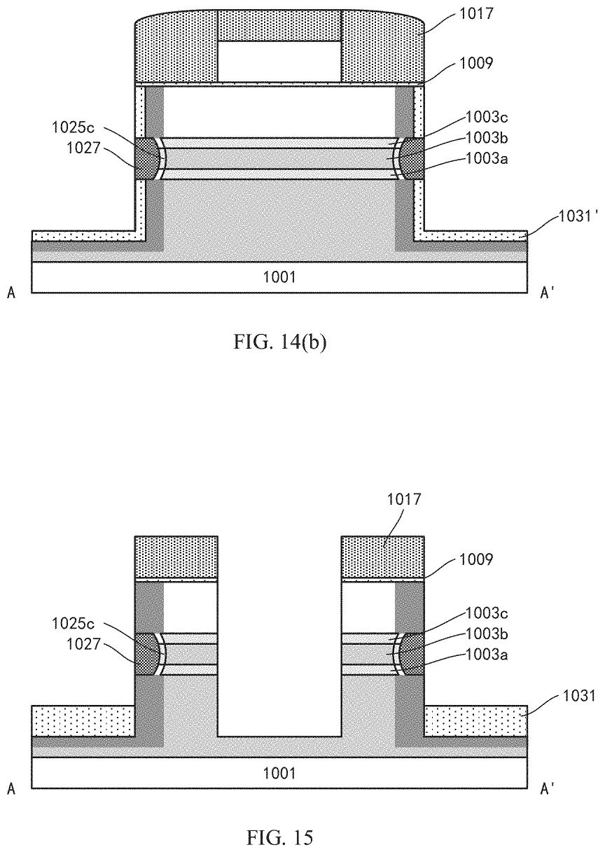

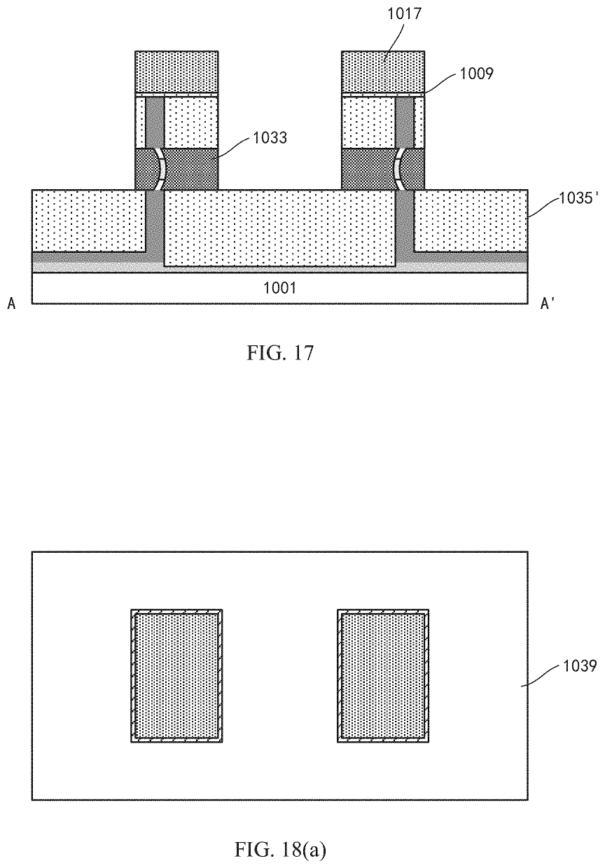

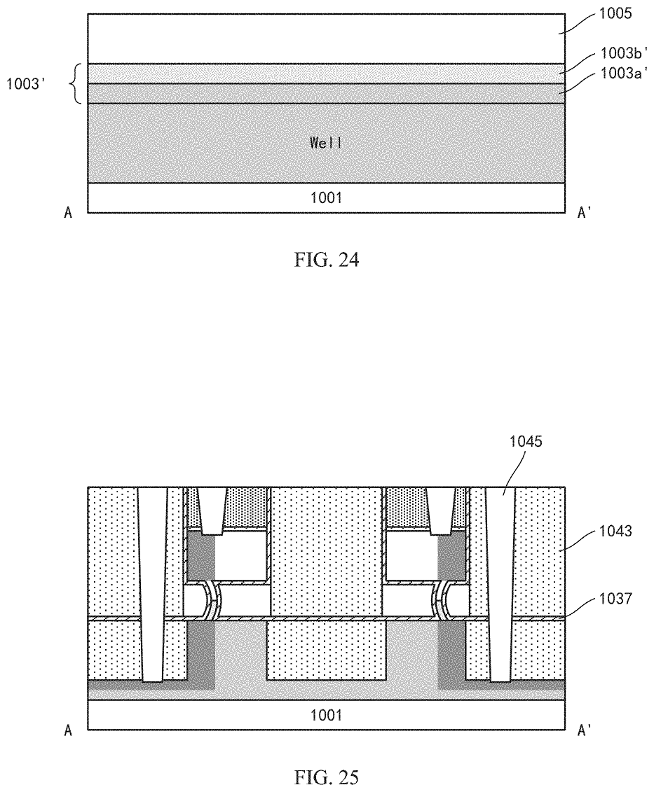

FIG. 1 to FIG. 4, FIG. 5(b), FIG. 6(b), FIG. 7 to FIG. 9, FIG. 10(a), FIG. 10(b), FIG. 11 to FIG. 13, FIG. 14(a), FIG. 14(b), FIG. 15, FIG. 16(a), FIG. 17, FIG. 18(b), FIG. 20(b), FIG. 21(b), FIG. 24, and FIG. 25 are cross-sectional views taken along AA′ line;

FIG. 6(c) is a cross-sectional view taken along line BB′;

FIG. 5(c) and FIG. 6(d) are cross-sectional views taken along line CC′;

FIG. 16(b), FIG. 18(c), and FIG. 20(c) are cross-sectional views taken along line DD′.

Throughout the drawings, the same or similar reference numerals indicate the same or similar components.

### DETAILED DESCRIPTION OF EMBODIMENTS

Embodiments of the present disclosure will be described below with reference to the accompanying drawings. It should be understood, however, that these descriptions are merely exemplary and are not intended to limit the scope of the present disclosure. In addition, in the following descriptions, descriptions of well-known structures and technologies are omitted to agap unnecessarily obscuring the concept of the present disclosure.

Various schematic structural diagrams according to the embodiments of the present disclosure are shown in the accompanying drawings. The drawings are not drawn to scale. Some details are enlarged and some details may be omitted for clarity of presentation. Shapes of the various regions, layers as well as a relative size and a positional relationship thereof shown in the drawings are only exemplary. In practice, there may be deviations due to manufacturing tolerances or technical limitations, and those skilled in the art may additionally design regions/layers with different shapes, sizes, and relative positions according to actual needs.

In the context of the present disclosure, when a layer/element is referred to as being located “on” another layer/element, the layer/element may be directly on the another layer/element, or there may be an intermediate layer/element therebetween. In addition, if a layer/element is located “on” another layer/element in one orientation, the layer/element may be located “under” the another layer/element when the orientation is reversed.

According to the embodiments of the present disclosure, there is provided a vertical metal oxide semiconductor field effect transistor (MOSFET) having an active region disposed vertically (e.g., in a direction substantially perpendicular to a substrate surface) on a substrate. A channel portion may be a vertical nanosheet or nanowire, such as a curved nanosheet or nanowire having a C-shaped cross section (e.g., a cross section perpendicular to the substrate surface), and may have a non-uniform doping, so the MOSFET may called a Non-Uniform FET (that is, NUDFET). As described below, a nanosheet or nanowire may be formed by an epitaxial growth, and thus the nanosheet or nanowire may be a unitary monolith, and may have a substantially uniform thickness.

The MOSFET may further include source/drain portions disposed at upper and lower ends of the channel portion, respectively. The source/drain portions may have a certain doping. For example, for a p-type MOSFET (pMOSFET), the source/drain portions may have a p-type doping; for an n-type MOSFET (nMOSFET), the source/drain portions may have an n-type doping.

As mentioned above, the channel portions may have a non-uniform doping (in a vertical direction) to adjust a threshold voltage of the device. More specifically, for an nMOSFET, a threshold voltage of a first portion of the channel portion close to one (which may serve as a drain electrode) of the source/drain portions may be lower than a threshold voltage of a second portion adj acent to the first portion; for a pMOSFET, the threshold voltage of the first portion may be higher than the threshold voltage of the second portion. This may be achieved by making the first portion have a relatively low doping (including a case of an unintentionally doping, i.e., a substantially zero doping) and the second portion have a relatively high doping. A conductivity type of the doping may be opposite to a conductivity type (in other words, a conductivity type of the source/drain portions) of the device. This may help suppress a gate induced drain leakage (GIDL).

The second portion of the channel portion may be a substantially middle portion of the channel portion (in the vertical direction). A third portion of the channel portion adjacent to the other source/drain portion (which may serve as a source electrode) may have substantially the same doping as or similar doping to that of the first portion, and thus have substantially the same or similar threshold voltage. Thus, the channel portion may exhibit a low-high-low doping concentration distribution in the vertical direction. In the vertical direction, the second portion is located between the first portion and the third portion, and the first portion and the third portion may be disposed substantially symmetrically with respect to the second portion.

The second portion of the channel portion may extend to adjoin the other source/drain portion (which may serve as a source electrode). Thus, the channel portion may exhibit a low-high or high-low doping concentration distribution in the vertical direction (depending on which of upper and lower source/drain portions is used as a drain electrode, wherein a low doping concentration portion may be close to the drain electrode).

The source/drain portions may be provided in a corresponding semiconductor layer. For example, the source/drain portions may be doped regions in the corresponding semiconductor layer. The source/drain portions may be part or all of the corresponding semiconductor layer. When the source/drain portions are part of the corresponding semiconductor layer, there may be a doping concentration interface between the source/drain portions and the rest of the corresponding semiconductor layer. As described below, the source/drain portions may be formed by a diffusion doping. In this case, the doping concentration interface may be substantially in a vertical direction with respect to the substrate.

The channel portion may contain a single crystal semiconductor material. Certainly, the source/drain portions or a semiconductor layer o which the source/drain portions are formed may also contain a single crystal semiconductor material. For example, they may all be formed by an epitaxial growth.

The MOSFET may also include a gate stack disposed on the channel portion and opposite to the channel portion. For example, the gate stacks may be provided on two opposite sides of the channel portion (a dual gate configuration is thus obtained), or may surround a perimeter of the channel portion (a gate-all-around configuration is thus obtained). According to the embodiments of the present disclosure, the gate stack may be self-aligned to the channel portion. For example, a portion of the gate stack at least close to the channel portion may be substantially coplanar with the channel portion, e.g., the portion of the gate stack and upper and/or lower surfaces of the channel portion are substantially coplanar with each other.

Such a MOSFET may be manufactured, for example, as follows.

According to the embodiment, a stack of a first material layer, a second material layer and a third material layer may be provided on the substrate. The first material layer may define a position of a lower-end source/drain portion, the second material layer may define a position of the gate stack, and the third material layer may define a position of an upper-end source/drain portion. The first material layer may be provided through the substrate, e.g., an upper portion of the substrate, and the second material layer and the third material layer may be sequentially formed on the first material layer by, for example, an epitaxial growth. Alternatively, the first material layer, the second material layer and the third material layer may be sequentially formed on the substrate by, for example, an epitaxial growth.

The second material layer may include a first sublayer and a second sublayer divided based on a doping concentration. For example, the second sublayer may be highly doped with respect to the first sublayer. A doping concentration distribution (in the vertical direction) in the second material layer may define a doping concentration distribution (in the vertical direction) in a subsequently formed channel portion. For example, the doping concentration distribution may be achieved by an in-situ doping at different concentrations during an epitaxial growth. According to the doping concentration distribution (e.g., the above-mentioned low-high-low doping concentration distribution) in the channel portion required to be achieved, the second material layer may further include other sublayers.

The MOSFET may be manufactured based on the stack. The stack may include first and second sides opposite to each other in a first direction and third and fourth sides opposite to each other in a second direction intersecting (e.g., perpendicular to) the first direction. For example, the stack may be quadrilateral such as rectangular or square in a top view. Channel portions may be formed on a pair of opposite sidewalls (e.g., the first and second sides) of the stack.

A sidewall of the second material layer may be laterally recessed (in the second direction) with respect to sidewalls of the first material layer and the third material layer on the third and fourth sides of the stack, so as to define a first recessed portion. The first recessed portion may define a space for the gate stack (e.g., in a case of a gate-all-around configuration). The first recessed portion may have a curved surface that is recessed toward an inner side of the stack. A first position maintaining layer may be formed in the first recessed portion.

Similarly, the sidewall of the second material layer may be recessed laterally (in the first direction) with respect to the sidewalls of the first material layer and the third material layer on the first and second sides of the stack, so as to define a second recessed portion. The second recessed portion may define a space for the gate stack. The second recessed portion may have a curved surface that is recessed toward an inner side of the stack. A channel portion may be formed on a surface of the second recessed portion. For example, a first active layer may be formed by an epitaxial growth on an exposed surface of the stack, and a portion of the first active layer on the surface of the second recessed portion may serve as the channel portion (which is also referred to as “channel layer”). A device may be formed based on the first active layers on the sidewalls of the first and second sides of the stack. Thus, two devices opposite to each other may be formed based on a single stack. A second position maintaining layer may be formed in the second recessed portion having the channel layer formed on the surface.

After the second recessed portion is defined and before the first active layer is formed, the exposed surface of the stack may also be etched back by a certain amount, e.g., approximately a thickness of a to-be-formed first active layer. This may help ensure that the subsequently formed gate stack have substantially equal gate lengths on two opposite sides of the channel portion.

A dopant in the second material layer may be driven laterally (in the first direction) into the first active layer by, for example, annealing, so that a corresponding doping concentration distribution may be formed in a portion (i.e., the channel portion) of the first active layer corresponding to the second material layer. For example, a portion of the first active layer corresponding to the second sublayer of the second material layer may have a relatively high doping concentration, while a portion of the first active layer corresponding to the first sublayer of the second material layer may have a relatively low (even zero) doping concentration distribution.

The source/drain portions may be formed in the first material layer and the third material layer. For example, the source/drain portions may be formed by doping the first material layer and the third material layer. The doping may include an in-situ doping during an epitaxial growth of the first material layer and the third material layer, or an additional doping after the first material layer and the third material layer are grown. The additional doping may be achieved by a solid phase dopant source layer. For example, a dopant in the solid phase dopant source layer may be driven (in a lateral direction) into the first material layer and the third material layer by annealing so as to form the source/drain portions. The annealing and the above-mentioned annealing by which the dopant is driven from the second material layer into the first active layer may be achieved by a single annealing process.

An opening may be formed in the stack to separate active regions of two devices. The opening may extend in the second direction, so as to divide the stack into two portions respectively located on the first and second sides. The two portions have respective channel layers. The second material layer may be replaced with a third position maintaining layer through the opening. The third position maintaining layer may define the space for the gate stack.

The second position maintaining layer and the third position maintaining layer (and optionally, the first position maintaining layer) may be replaced with a gate stack through a replacement gate process, so that the gate stack may be formed.

According to the embodiments of the present disclosure, a thickness and a gate length of a nano sheet or nanowire used as the channel portion are mainly determined by an epitaxial growth instead of an etching or photolithography, and thus may have a good channel size/thickness and gate length control.

The present disclosure may be presented in various forms, some examples of which will be described below. In the following descriptions, a selection of various materials is involved. In the selection of material, in addition to a function of the material (for example, a semiconductor material is used for forming an active region, a dielectric material is used for forming an electrical isolation), an etching selectivity is also considered. In the following descriptions, a desired etch selectivity may or may not be indicated. It should be clear to those skilled in the art that when etching a material layer is mentioned below, if it is not mentioned or shown that other layers are also etched, then the etching may be selective, and the material layer may have an etching selectivity relative to other layers exposed to the same etching recipe.

FIG. 1 to FIG. 22 schematically show some stages in a process of manufacturing a MOSFET according to an embodiment of the present disclosure.

As shown in FIG. 1, a substrate 1001 (an upper portion of which may form the above-mentioned first material layer) is provided. The substrate 1001 may be a substrate in various forms, including but not limited to a bulk semiconductor material substrate such as a bulk Si substrate, a semiconductor-on-insulator (SOI) substrate, a compound semiconductor substrate such as a SiGe substrate, and the like. In the following descriptions, for ease of explanation, a bulk Si substrate is taken as an example for description. Here, a silicon wafer is provided as the substrate 1001.

In the substrate 1001, a well region may be formed. If a p-type MOSFET (pMOSFET) is to be formed, the well region may be an n-type well; if an n-type MOSFET (nMOSFET) is to be formed, the well region may be a p-type well. The well region may be formed by, for example, implanting a dopant of a corresponding conductivity type (a p-type dopant such as B or In, or an n-type dopant such as As or P) into the substrate 1001 and a subsequent thermal annealing. The well region may be set in various ways in the art, which will not be repeated here.

A second material layer 1003 and a third material layer 1005 may be formed on the substrate 1001 by, for example, an epitaxial growth. The second material layer 1003 may be used to define a position of the gate stack. The third material layer 1005 may be used to define a position of the upper-end source/drain portion. A thickness of the third material layer 1005 is, for example, about 20 nm to 200 nm.

Adjacent layers in the substrate 1001 and the second material layer 1003 and the third material layer 1005 formed thereon may have an etch selectivity with respect to each other. For example, when the substrate 1001 is a silicon wafer, the second material layer 1003 may contain SiGe (an atomic percent of Ge is, for example, about 10% to 30%), and the third material layer 1005 may contain Si.

In order to form a certain doping concentration distribution in a subsequently formed channel portion so as to achieve a non-uniformly doped channel portion, the second material layer 1003 may include a concentration distribution in a vertical direction (z direction). For example, the second material layer 1003 may be divided into a first sublayer 1003a, a second sublayer 1003b and a third sublayer 1003c stacked in sequence in the z direction according to a doping concentration. A doping concentration in the second sublayer 1003b is higher than that in the first sublayer 1003a and the third sublayer 1003c. For example, the first sublayer 1003a and the third sublayer 1003c may be unintentionally doped or relatively low doped, while the second sublayer 1003b may be relatively highly doped, for example, at a doping concentration of about 10¹⁸cm⁻³ to about 10²¹ cm⁻³. This may be achieved by an in-situ doping at different concentrations during an epitaxial growth. A doped conductivity type may be a p-type (for an nMOSFET) or an n-type (for a pMOSFET).

A thickness of the second material layer 1003 (or each of the first sublayer 1003a, the second sublayer 1003b, and the third sublayer 1003c) may be determined according to a size of the channel portion. For example, the thickness of the first sublayer 1003a may be about 10 nm to 30 nm, the thickness of the second sublayer 1003b may be about 20 nm to 50 nm, and the thickness of the third sublayer 1003c may be about 10 nm to 30 nm.

FIG. 1 schematically show lateral directions x, y and a vertical direction z. The x, y directions may be parallel to a top surface of the substrate 1001 and may intersect, e.g., perpendicular to, each other; the z direction may be substantially perpendicular to the top surface of the substrate 1001. The x direction may correspond to the above-mentioned first direction, and the y direction may correspond to the above-mentioned second direction.

According to the embodiment, a spacer pattern transfer technique will be used in the following compositions. In order to form a spacer, a mandrel may be formed. For example, as shown in FIG. 2, a layer 1011 for a mandrel pattern may be formed on the third material layer 1005 by, for example, deposition. For example, the layer 1011 for the mandrel pattern may contain amorphous silicon or polysilicon with a thickness of about 50 nm to 150 nm. In addition, in order to achieve a better etching control, an etch stop layer 1009 may be formed first by, for example, deposition. For example, the etch stop layer 1009 may contain an oxide (e.g., silicon oxide) with a thickness of about 1 nm to 10 nm.

A hard mask layer 1013 may be formed by, for example, deposition, on the layer 1011 for the mandrel pattern. For example, the hard mask layer 1013 may contain a nitride (e.g., silicon nitride) with a thickness of about 30 nm to 100 nm.

The layer 1011 for the mandrel pattern may be patterned into a mandrel pattern.

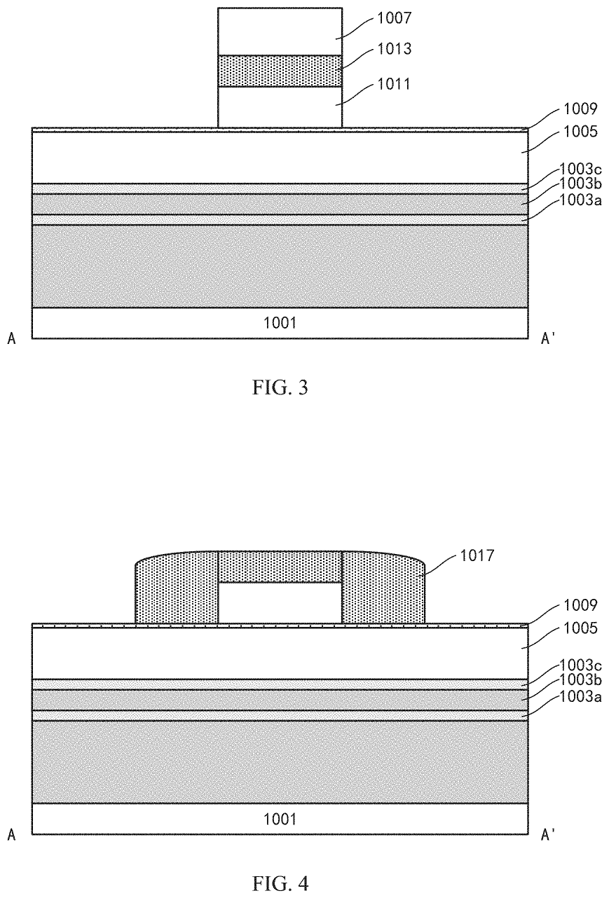

For example, as shown in FIG. 3, a photoresist 1007 may be formed on the hard mask layer 1013 and patterned into a strip extending in the y direction by photolithography. By using the photoresist 1007 as an etching mask, the hard mask layer 1013 and the layer 1011 for the mandrel pattern may be sequentially selectively etched by, for example, Reactive Ion Etching (RIE), and a pattern of the photoresist is transferred to the hard mask layer 1013 and the layer 1011 for the mandrel pattern. The RIE may proceed in the z direction and may be stopped at the etch stop layer 1009. After that, the photoresist 1007 may be removed.

As shown in FIG. 4, spacers 1017 may be formed on sidewalls on two opposite sides of the mandrel pattern 1011 in the x direction. For example, a layer of nitride with a thickness of about 10 nm to 100 nm may be deposited in a substantially conformal manner, and then the deposited nitride layer may be anisotropically etched, such as RIE (which may be stopped at the etch stop layer 1009), in the z direction to remove a lateral extension portion thereof and leave a vertical extension portion thereof, so that the spacers 1017 may be obtained. The spacers 1017 may then be used to define a position of an active region of the device.

The mandrel pattern formed as described above and the spacer 1017 formed on a sidewall thereof extend in the y direction, their extent in the y direction may be defined, and thus an extent of the active region of the device in the y direction may be defined.

As shown in FIG. 5(a) to FIG. 5(c), a photoresist 1015 may be formed on the structure shown in FIG. 4 and patterned by photolithography to occupy a certain extent in the y direction, e.g. a strip extending in the x direction. A lower layer may be selectively etched sequentially by, for example, RIE in the z direction, by using the photoresist 1015 as an etching mask. The etching may proceed into the substrate 1001, particularly a well region therein, so that a groove may be formed in the substrate 1001. An isolation, such as a Shallow Trench Isolation (STI), may then be formed in the formed trench. After that, the photoresist 1015 may be removed.

As shown in FIG. 5(c), a sidewall of the second material layer 1003 in the y direction is currently exposed.

According to the embodiments of the present disclosure, in order to form a gate stack surrounding the channel portion, the space for the gate stack may be reserved at both ends of the second material layer 1003 in the y direction.

To this end, as shown in FIG. 6(a) to FIG. 6(d), the second material layer 1003 may be selectively etched, so that the sidewall of the second material layer 1003 in the y direction is relatively recessed to form a recessed portion. In order to better control an amount of etching, an Atomic Layer Etching (ALE) may be used. For example, the amount of etching may be about 5 nm to 20 nm. Depending on characteristics of the etching, such as an etching selectivity of the second material layer 1003 with respect to the substrate 1001 and the third material layer 1005, the sidewall of the second material layer 1003 may have a different shape after the etching. FIG. 6(d) shows that the sidewall of the second material layer 1003 has a C-shape that is recessed after the etching. However, the present disclosure is not limited to this. For example, when there is a good etching selectivity, the sidewall of the second material layer 1003 may be nearly vertical after the etching. Here, the etching may be isotropic, especially when a larger etching amount is required. A dielectric material may fill the recessed portion thus formed so as to define the space for the gate stack. The filling may be performed by deposition and then etch back. For example, a dielectric material, such as SiC, that is sufficient to fill the recessed portion may be deposited on the substrate, and then the deposited dielectric material may be etched back by, for example, RIE in the z direction. In this way, the dielectric material may be left in the recessed portion to form a first position maintaining layer 1019.

According to the embodiments of the present disclosure, a protective layer 1021 may also be formed on the substrate 1001. For example, an oxide layer may be formed on the substrate 1001 by deposition, and the deposited oxide layer may be planarized, such as Chemical Mechanical Polishing (CMP) (CMP may be stopped at the hard mask layer 1013), and then further etched back so as to form the protective layer 1021. Here, the protective layer 1021 may be located in the groove of the substrate 1001, and a top surface of the protective layer 1021 is lower than the top surface of the substrate 1001. In addition, during the etching back, an exposed portion of the etch stop layer 1009 (which is also an oxide in this example) may also be etched. According to other embodiments, an operation of forming the protective layer 1021 may be performed before an operation (including recessing and filling) of forming the first position maintaining layer 1019.

The protective layer 1021 may protect a surface of the substrate 1001 in the following processes. For example, in this example, an extent of the active region in the y direction is first defined. Subsequently, an extent of the active region in the x direction will be defined. The protective layer 1021 may agap affecting the surface (see FIG. 5(c)) of the substrate that is currently exposed in the groove when the extent in the x direction is defined. In addition, when different types of well regions are formed in the substrate 1001, the protective layer 1021 may protect a pn junction between the different types of well regions from being damaged by the etching.

As shown in FIG. 7, the third material layer 1005, the second material layer 1003 and the upper portion (the first material layer) of the substrate 1001 may be patterned into a ridge structure by using the hard mask layer 1013 and the spacer 1017 (in fact, an extent of the ridge structure in the y direction has been defined by the above-mentioned process). For example, each layer may be selectively etched in sequence by, for example, RIE in the z direction, with the hard mask layer 1013 and the spacer 1017 as etching masks, and the pattern may be transferred to the lower layer. Thus, the upper portion of the substrate 1001, the second material layer 1003 and the third material layer 1005 may form a ridge structure. As described above, due to a presence of the protective layer 1021, the etching may not affect portions of the substrate 1001 on both sides of the ridge structure in the y direction.

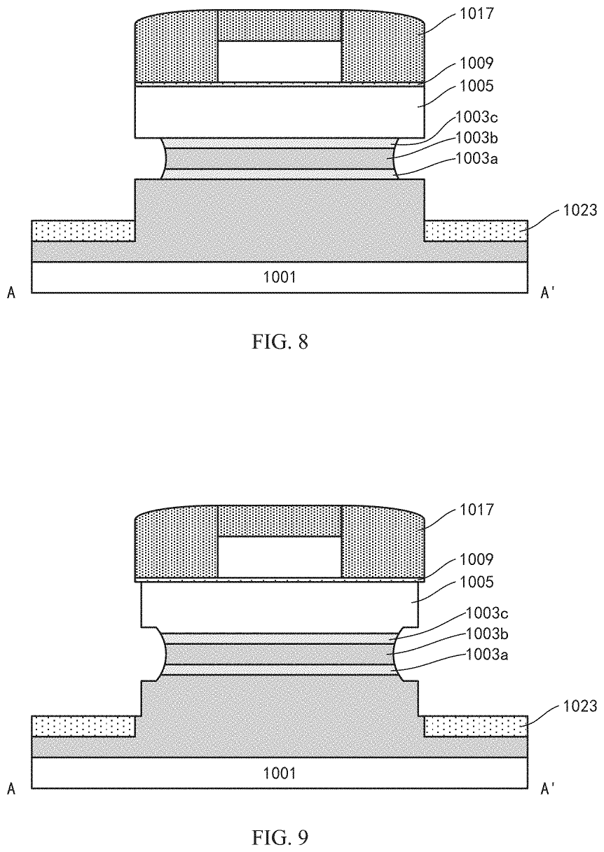

Here, the etching may proceed into a well region of the substrate 1001. A degree of the etching into the substrate 1001 may be substantially the same as or similar to a degree of the etching into the substrate 1001 described above in connection with FIG. 5(a) to FIG. 5(c). Similarly, grooves may be formed in the substrate 1001. A protective layer (see 1023 in FIG. 8) may also be formed in the grooves. The protective layer 1023, together with the previous protective layer 1021, surrounds a periphery of the ridge structure. In this way, a similar processing condition may be provided around the ridge structure, that is, grooves may be formed in the substrate 1001 and the protective layers 1021 and 1023 are formed in the grooves.

Similarly, in order to form a gate stack surrounding the channel portion, the space for the gate stack may be reserved at both ends of the second material layer 1003 in the x direction. For example, as shown in FIG. 8, the second material layer 1003 may be selectively etched, so that the sidewall of the second material layer 1003 in the x direction is relatively recessed to form a recessed portion (which may define the space for the gate stack). In order to better control an amount of etching, an ALE may be used. For example, the amount of etching may be about 10 nm to 40 nm. As described above, the sidewall of the second material layer 1003 may have a C-shape that is recessed after the etching. Here, the etching may be isotropic, especially when a larger etching amount is required. Generally, the C-shaped sidewall of the second material layer 1003 has a greater curvature at upper and lower ends and a less curvature at a waist or middle portion.

A first active layer may be formed on a sidewall of the ridge structure so as to subsequently define the channel portion. In order to keep the gate lengths (e.g., in the z direction) substantially equal when the gate stacks are subsequently formed on left and right sides of the channel portion, as shown in FIG. 9, the ridged structure (specifically, exposed surfaces of the first material layer, the second material layer and the third material layer) may be back etched. In order to control an etching depth, the ALE may be used. The etching depth may be substantially equal to a thickness of a subsequently grown first active layer, e.g., about 5 nm to 15 nm.

Then, as shown in FIG. 10(a), a first active layer 1025 may be formed on the sidewall of the ridge structure by, for example, a selective epitaxial growth. Due to the selective epitaxial growth, the first active layer 1025 may not be formed on a surface of the first position maintaining layer 1019. The first active layer 1025 may then define a channel portion with a thickness of, for example, about 3 nm to 15 nm. Since the channel portion (although it may be C-shaped) extends substantially in the vertical direction, the first active layer 1025 (especially a portion of the first active layer 1025 on the sidewall of the second material layer 1003) may also be referred to as a (vertical) channel layer. According to the embodiments of the present disclosure, a thickness of the first active layer 1025 (which is subsequently used as the channel portion) may be determined by an epitaxial growth process, and thus the thickness of the channel portion may be better controlled.

In FIG. 10(a), sidewalls of portions of the first active layer 1025 on the sidewalls of the first material layer and the third material layer are shown to be substantially flush with sidewalls of the spacers 1017. This may be achieved by controlling an amount of etching back to be substantially the same as an epitaxial growth thickness. However, the present disclosure is not limited to this. For example, the sidewalls of the portions of the first active layer 1025 on the sidewalls of the first material layer and the third material layer may be recessed with respect to the sidewalls of the spacers 1017, or may even protrude.

Here, the above-mentioned etching back of the ridge structure may etch upper and lower ends of the recessed portion upward and downward respectively, so that a height t1 of the recessed portion may be substantially the same as a thickness t2 of the second material layer 1003 after the first active layer 1025 is grown. In this way, gate stacks subsequently formed on left and right sides of the first active layer 1025 may have substantially equal gate lengths. However, the present disclosure is not limited to this. According to the embodiments of the present disclosure, a gate length outside the first active layer 1025 may also be changed by adjusting the amount of etching back, so that a ratio of the gate lengths on both sides may be changed, so as to optimize an influence on a device performance due to different topographies on left and right sides of the C-shaped channel portion.

An etching recipe may be selected, so that the upper and lower ends of the recessed portion may be etched upward and downward by substantially the same amount. Therefore, the height-increased recessed portion may be self-aligned with the second material layer 1003, so that the gate stacks subsequently formed on the left and right sides of the first active layer 1025 may be self-aligned with each other.

A material of the first active layer 1025 may be appropriately selected according to performance requirements of the device. For example, the first active layer 1025 may contain various semiconductor materials, such as elemental semiconductor materials such as Si, Ge, etc., or compound semiconductor materials such as SiGe, InP, GaAs, InGaAs, etc. In this example, the first active layer 1025 may contain Si, which is the same as the first material layer and the third material layer.

In the example of FIG. 10(a), the first active layers 1025 on two opposite sides of the ridge structure in the x direction may have substantially the same characteristics (e.g., materials, dimensions, doping characteristics, etc.), and may be symmetrically disposed on two opposite sides of the second material layer. However, the present disclosure is not limited to this. As described below, two devices opposite to each other may be formed through a single ridge structure. According to design performance requirements of the two devices, the first active layers 1025 on two opposite sides of the ridge structure may have different characteristics, for example, in at least one aspect of thicknesses, materials and doping characteristics. This may be achieved by shielding one device region while growing the first active layer in another device region.

In one example, as shown in FIG. 10(b), an etch stop layer 1025a and a first active layer 1025b may be sequentially formed on the sidewall of the ridge structure by, for example, a selective epitaxial growth. The etch stop layer 1025a may define an etch stop position when the second material layer 1003 is subsequently etched (this is because in this example, both the first active layer 1025b and the second material layer 1003 contain SiGe, and if the etch stop layer 1025a is not provided, the first active layer 1025b may be affected when the second material layer 1003 is etched). A thickness of the etch stop layer 1025a is, for example, about 1 nm to 5 nm. The first active layer 1025b may then define the channel portion as described above, with a thickness of, for example, about 3 nm to 15 nm. A lattice constant of a material of the first active layer 1025b in the absence of strain may be different from a lattice constant of a material of the second material layer 1003 in the absence of strain, so as to generate a stress in the channel portion to enhance a device performance. In this example, the etch stop layer 1025a may contain Si, and the first active layer 1025b may contain SiGe. For example, in order to achieve a compressive stress, an atomic percentage of Ge in the first active layer 1025b may be greater than an atomic percentage of Ge in the second material layer 1003.

Certainly, other different semiconductor materials, such as III-V compound semiconductor materials, may be grown to achieve a desired strain or stress.

In the following, for the sake of convenience, the case in FIG. 10(a) will still be taken as an example for description.

In the recessed portion, a gate stack may be formed subsequently. In order to prevent a subsequent processing from leaving an unnecessary material in the gap or affecting the first active layer 1025, as shown in FIG. 11, a second position maintaining layer 1027 may be formed in the recess. Similarly, the second position maintaining layer 1027 may be formed by deposition and then etch back, and may contain a dielectric material such as SiC. In this example, the first position maintaining layer 1019 and the second position maintaining layer 1027 contain the same material, so that they may be subsequently removed together by the same etching recipe. However, the present disclosure is not limited to this. For example, the first position maintaining layer 1019 and the second position maintaining layer 1027 may contain different materials.

In FIG. 11 and the subsequent drawings, for the ease of illustration, a portion of the first active layer 1025 adjacent to the third material layer 1005 is shown as being integral with the third material layer 1005.

After that, a source/drain doping may be performed.

As shown in FIG. 12, a solid phase dopant source layer 1029 may be formed on the structure shown in FIG. 11 by, for example, deposition. The solid phase dopant source layer 1029 may be formed in a substantially conformal manner. For example, the solid phase dopant source layer 1029 may be a dopant-containing oxide having a thickness of about 1 nm to 5 nm. A dopant contained in the solid phase dopant source layer 1029 may be used to dope the source/drain portions (and optionally, an exposed surface of the substrate 1001), and thus may have the same conductivity type as the source/drain portions required to be formed. For example, for a pMOSFET, the solid phase dopant source layer 1029 may contain a p-type dopant such as B or In; for an nMOSFET, the solid phase dopant source layer 1029 may contain an n-type dopant such as P or As. The dopant of the solid phase dopant source layer 1029 may have a concentration of about 0.1% to 5%.

In this example, before the solid phase dopant source layer 1029 is formed, the protective layers 1021, 1023 may be selectively etched by, for example, RIE, to expose the surface of the substrate 1001. In this way, the exposed surface of the substrate 1001 may also be doped to form respective contact regions of the lower-end source/drain portions S/D of the two devices.

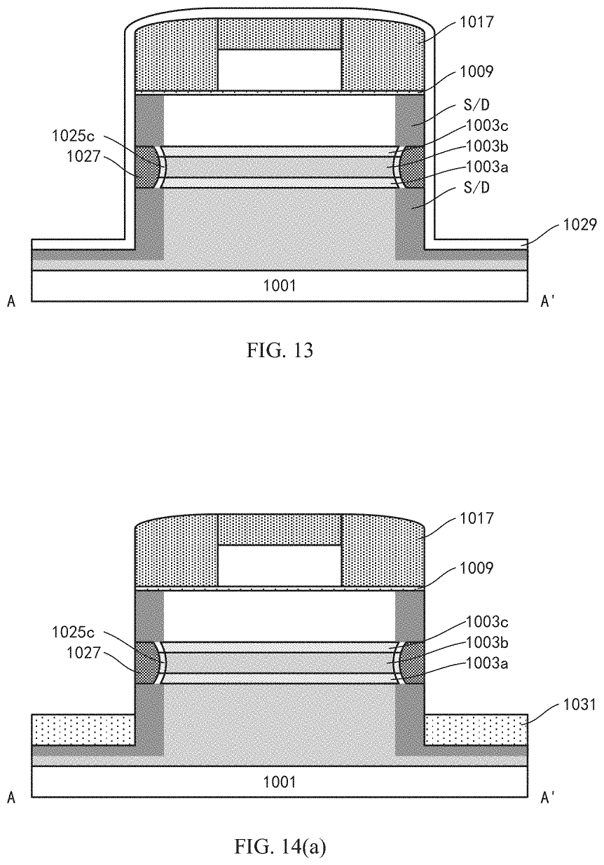

The dopant in the solid phase dopant source layer 1029 may be driven into the first material layer and the third material layer by an annealing process so as to form the source/drain portions S/D (and optionally, may be driven into the exposed surface of the substrate 1001 so as to form the respective contact regions of the lower-end source/drain portions S/D of the two devices), as shown in FIG. 13. After that, the solid phase dopant source layer 1029 may be removed.

A condition (e.g., time) of the annealing process may be controlled, so that dopants are mainly driven into the first material layer and the third material layer in the lateral direction. Since the first material layer and the third material layer may contain the same material, and the solid phase dopant source layer 1029 may be formed on their surfaces in a substantially conformal manner, the dopants may be driven from the solid phase dopant source layer 1029 into the first material layer and the third material layer to approximately the same extent. Therefore, a/an (doping concentration) interface of (between inner portions of the first material layer and the third material layer and) the source/drain portions S/D may be approximately parallel to surfaces of the first material layer and the third material layer, that is, they may be aligned with each other in the vertical direction.

A portion of the first active layer 1025 on the sidewall of the first material layer currently has substantially the same doping as a portion of the first material layer around the first active layer 1025 (the lower-end source/drain portions S/D are thus formed). Therefore, for ease of illustration, the interface between the source/drain portions S/D will not be shown in the following drawings.

In this example, the first material layer is provided through the upper portion of the substrate 1001. However, the present disclosure is not limited to this. For example, the first material layer may also be an epitaxial layer on the substrate 1001. In this case, the first material layer and the third material layer may be doped in-situ epitaxially, rather than doped using the solid phase dopant source layer.

In addition, during the annealing process, the dopant in the second material layer 1003 may also be driven into the first active layer 1025, so that a corresponding doping distribution may be formed in the first active layer 1025 (a portion of the first active layer 1025 on the sidewall of the second material layer 1003). In this example, a relatively high doping concentration (e.g., about 10¹⁸ cm⁻³ to about 10²¹cm⁻³) may be formed in a portion 1025c of the first active layer 1025 corresponding to the second sublayer 1003b, and there may be an unintentional doping or relatively low doping in portions of the first active layer 1025 corresponding to the first sublayer 1003a and the third sublayer 1003c. A desired doping concentration distribution in the first active layer 1025 may be achieved by setting the number, arrangement, doping concentration, etc. of the sublayers in the second material layer 1003.

In grooves around the ridge structure, an isolation layer 1031 such as a Shallow Trench Isolation (STI) may be formed, as shown in FIG. 14(a). A method for forming the isolation layer may be similar to the method for forming the protective layers 1021 and 1023 as described above, and will not be repeated here.

In order to reduce a capacitance between a gate and a source/drain, an overlap between the gate and the source/drain may be further reduced. For example, as shown in FIG. 14(b), after the solid phase dopant source layer 1029 is removed, exposed surfaces of the first material layer and the third material layer may be further recessed by a selective etching, so that an overlap between the source/drain portions S/D formed in the first material layer and the third material layer, and the first position maintaining layer 1019 and the second position maintaining layer 1027 (which may subsequently define a position of the gate stack) may be reduced. A dielectric material 1031′ such as an oxynitride or oxide may fill a gap formed below the hard mask layer 1013 and the spacers 1017 due to recessed surfaces of the first material layer and the third material layer. The filling may be achieved by deposition (and planarization) and then etch back. A certain thickness of the dielectric material 1031′ is left on the surface of the substrate 1001 during the etching back, so that an isolation portion may be formed.

In the following, for the sake of convenience, the case shown in FIG. 14(a) will still be taken as an example for description.

Next, the spacers 1017 may be used to complete a definition of the active region.

As shown in FIG. 15, the hard mask layer 1013 may be removed by a selective etching such as RIE or a planarization process such as CMP, so as to expose the mandrel pattern 1011. During the removal of the hard mask layer 1013, a height of the spacer 1017, which is also a nitride in this example, may decrease. Then, the mandrel pattern 1011 may be removed by a selective etching such as a wet etching using a TMAH solution or dry etching using RIE. In this way, a pair of spacers 1017 extending opposite to each other are left on the ridge structure (when the height is reduced, a top morphology may also be changed).

The etch stop layer 1009, the third material layer 1005, the second material layer 1003 and the upper portion of the substrate 1001 may be selectively etched sequentially by using the spacers 1017 as etching masks by, for example, RIE in the z direction. The etching may proceed into the well region of the substrate 1001. In this way, a pair of stacks corresponding to the spacers 1017 are formed in a space surrounded by the isolation layer 1031, the third material layer 1005, the second material layer 1003 and the upper portion of the substrate 1001, so as to define the active region.

Certainly, a formation of the stack for defining the active region is not limited to the spacer pattern transfer technique, and may also be performed by photolithography using photoresist or the like.

Here, for the purpose of epitaxial growth, the second material layer 1003 for defining a position of the gate stack contains a semiconductor material. In order to facilitate a subsequent replacement gate process, the second material layer 1003 may be replaced with a dielectric material to form a third position maintaining layer.

For example, as shown in FIG. 16(a) and FIG. 16(b), the second material layer 1003 (SiGe in this example) may be removed by a selective etching with respect to the first active layer 1025, the substrate 1001 and the third material layer 1005 (all Si in this example). Then, a third position maintaining layer 1033 may be formed in a gap left below the spacer 1017 due to a removal of the second material layer 1003. Similarly, the third position maintaining layer 1033 may be formed by deposition and then etch back. In this example, the third position maintaining layer 1033 may contain the same material as that of the first position maintaining layer 1019 and the second position maintaining layer 1027, so that the third position maintaining layer 1033 may be subsequently removed by the same etching recipe in the replacement gate process.

As shown in FIG. 16(b), the first position maintaining layer 1019, the second position maintaining layer 1027 and the third position maintaining layer 1033 (which together may define the position of the gate stack) surround a portion of the first active layer 1025. The portion of the first active layer 1025 may serve as a channel portion. It may be indicated that the channel portion is a C-shaped curved nanosheet (when the nanosheet is narrow, for example, when a size of the nanosheet in a vertical direction (i.e., y direction) on a paper surface in FIG. 16(b) is small, the nanosheet may become a nanowire). Due to a high etching selectivity of the second material layer 1003 (SiGe) with respect to the first active layer 1025 (Si), a thickness (a thickness or diameter in a case of a nanowire) of the channel portion is substantially determined by a selective growth process of the first active layer 1025. This may have great advantages over a technique in which a thickness is determined by only an etching or photolithography, because an epitaxial growth process has a much better process control than the etching or photolithography.

In order to reduce an overlap between the gate stack and the source/drain portions, especially the source/drain portions located below, a height of the isolation layer 1031 may be increased. For example, an isolation layer 1035 may be formed by deposition (and planarization) and then etch back. For example, the isolation layer 1035 may contain an oxide, and may thus be shown being integral with the previous isolation layer 1031. A top surface of the isolation layer 1035 may be close to, for example, not lower than (preferably, slightly higher than) a top surface of the first material layer (i.e., the top surface of the substrate 1001) or a bottom surface of the second material layer (i.e., bottom surfaces of the first position maintaining layer 1019, the second position maintaining layer 1027, and the third position maintaining layer 1033), and not higher than a top surface of the second material layer (i.e., top surfaces of the first position maintaining layer 1019, the second position maintaining layer 1027, and the third position maintaining layer 1033) or a bottom surface of the third material layer.

According to another embodiment of the present disclosure, in order to reduce a capacitance, an overlap between the gate and the first and third material layers (in which the source/drain portions are formed) may be further reduced. For example, as shown in FIG. 17, after the third position maintaining layer 1033 is formed as described above, the exposed surfaces of the first material layer and the third material layer may be further recessed by a selective etching. Therefore, an overlap between the first and third material layers and the third position maintaining layer 1033 (which subsequently defines the position of the gate stack) may be reduced. After that, an isolation layer 1035′ may be similarly formed. In a process of forming the isolation layer 1035′, a dielectric material of the isolation layer 1035′ may also fill a gap formed by a recess of the third material layer below the spacers 1017.

In the example of FIG. 17, a structure obtained by performing a process of reducing an overlap described with reference to FIG. 17 in addition to the process of reducing an overlap described with reference to FIG. 14(b) is shown. Thus, a periphery of the source/drain portions S/D is surrounded by the dielectric material. However, the present disclosure is not limited to this. For example, the process of reducing an overlap described with reference to FIG. 14(b) and the process of reducing an overlap described with reference to FIG. 17 may be performed alternatively, or both may be performed.

In the following descriptions, the cases shown in FIG. 16(a) and FIG. 16(b) will still be taken as an example for description.

Next, a replacement gate process may be performed to form a gate stack.

As shown in FIG. 18(a) to FIG. 18(c), the first position maintaining layer 1019, the second position maintaining layer 1027 and the third position maintaining layer 1033 may be removed by a selective etching and the gate stack may be formed on the isolation layer 1035. A gate dielectric layer 1037 may be formed in a substantially conformal manner, and a gate conductor layer 1039 may be formed on the gate dielectric layer 1037 by, for example, deposition. The gate conductor layer 1039 may fill a space between the active regions. A planarization process such as CMP may be performed on the gate conductor layer 1039, and the CMP may be stopped at the spacer 1017. Then, the gate conductor layer 1039 may be etched back, so that a top surface of the gate conductor layer 1039 is lower than the above-mentioned top surfaces of the first position maintaining layer 1019, the second position maintaining layer 1027 and the third position maintaining layer 1033 (or, the top surface of the second material layer surface or the bottom surface of the third material layer), so as to reduce a capacitance between the source/drain portions and the gate stack. In this way, an end portion of the gate stack formed is embedded in a space where the first position maintaining layer 1019, the second position maintaining layer 1027 and the third position maintaining layer 1033 are located, to surround the channel portion.

For example, the gate dielectric layer 1037 may contain a high-k gate dielectric material such as HfO₂ with a thickness of, for example, about 1 nm to 5 nm. Before the high-k gate dielectric material is formed, an interface layer layer, e.g., an oxide formed by an oxidation process or deposition such as an Atomic Layer Deposition (ALD), may also be formed, with a thickness of about 0.3 nm to 1.5 nm. The gate conductor layer 1039 may contain a work function adjusting metal such as TiN, TaN, TiA1C, etc. and a gate conductive metal such as W, etc.

Currently, respective gate stacks of two devices are integrally connected to each other. According to a device design, the gate conductor layer 1039 may be disconnected between the two devices by, for example, photolithography, while a landing pad of a gate contact may also be patterned.

As shown in FIG. 19, a photoresist 1041 may be formed and patterned to shield a region where the landing pad of the gate contact is to be formed while exposing other regions. Then, as shown in FIG. 20(a) to FIG. 20(c), the gate conductor layer 1039 may be selectively etched, such as RIE in the z direction, by using the photoresist 1041 (and the spacer 1017) as a mas. The RIE may be stopped at the gate dielectric layer 1037. After that, the photoresist 1041 may be removed.

Thus, the gate conductor layer 1039 is substantially left and self-aligned below the spacer 1017, except that a portion of the gate conductor layer 1039 is protruded on one side of the spacer 1017 (an upper side in FIG. 20(a)) to serve as a landing pad. The gate conductor layer 1039 is separated between two opposite devices respectively below the opposite spacers 1017, and thus combined with the gate dielectric layer 1037 to define a gate stack for the two devices.

In this example, respective landing pads of the two devices are located on the same side of the spacer 1017. However, the present disclosure is not limited to this. For example, the respective landing pads of the two devices may be located on different sides of the spacer 1017.

So far, a device manufacturing has been basically completed. As shown in the drawings, the device includes a vertical channel portion, which may have a curved shape such as a C-shape. The channel portion may have a doping concentration distribution in the vertical direction, so that a portion of the channel portion close to the source/drain portion (e.g., a source/drain portion serving as a drain electrode) on one side may have a different threshold voltage from that of an adjacent portion. More specifically, for an nMOSFET, a threshold voltage of a portion (e.g., a portion corresponding to the first sublayer 1003a or the third sublayer 1003c) close to the source/drain portion on one side may be lower than a threshold voltage of an adjacent portion (e.g., a portion corresponding to the second sublayer 1003b); for a pMOSFET, the threshold voltage of the portion (e.g., the portion corresponding to the first sublayer 1003a or the third sublayer 1003c) close to the source/drain portion on one side may be higher than the threshold voltage of the adjacent portion (e.g., the portion corresponding to the second sublayer 1003b). As described further below, the configuration may suppress a GIDL.

In this example, gate stacks (gate-all-around configuration) are formed around the channel portion. However, the present disclosure is not limited to this. For example, the gate stacks may be formed on two opposite sides (left and right sides in the drawings) of the channel portion in the x direction, so that a dual gate configuration may be obtained. For example, this may be achieved by forming the first position maintaining layer using a material having an etch selectivity with respect to the second position maintaining layer and the third position maintaining layer, and selectively removing the second position maintaining layer and the third position maintaining layer in the replacement gate process while leaving the first position maintaining layer in the above-mentioned example. As described above, even in a case of a dual gate configuration, the gate stacks on two opposite sides may be self-aligned with each other.

Subsequently, various contact portions, interconnect structures, etc. may be manufactured.

For example, as shown in FIG. 21(a) and FIG. 21(b), a dielectric layer 1043 may be formed on the substrate by, for example, deposition and then planarization. Then, a contact hole may be formed and filled with a conductive material such as a metal, so as to form a contact portion 1045. The contact portion 1045 may include a contact portion penetrating the spacer 1017 and the etch stop layer 1009 and connected to the upper-end source/drain portion, a contact portion penetrating the dielectric layer 1043 and the isolation layer 1035 and connected to a contact region of the lower-end source/drain portion, and a contact portion penetrating the dielectric layer 1043 and connected to a landing pad of the gate conductor layer. As shown in FIG. 21(a) and FIG. 21(b), contact portions to contact regions of respective lower-end source/drain portions of two devices may be located on two opposite sides (left and right sides in the drawings) of the active region, respectively.

According to other embodiments of the present disclosure, a contact portion to a contact region of the lower-end source/drain portion and a contact portion of a landing pad to a gate conductor layer of a corresponding device may be located on two opposite sides of an active region of the corresponding device, as shown in FIG. 22.

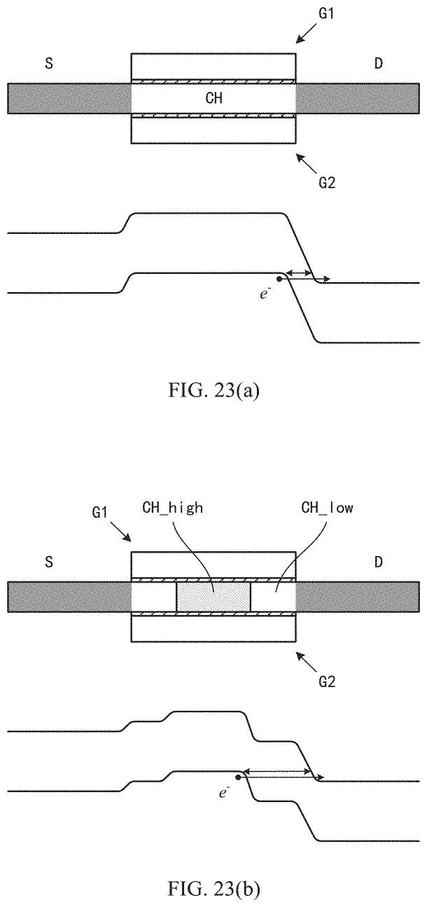

FIG. 23(a) and FIG. 23(b) respectively show an energy band diagram of an nMOSFET according to a comparative example and an energy band diagram of an nMOSFET according to an embodiment of the present disclosure.

As shown in FIG. 23(a), in the nMOSFET according to the comparative example, a source region S and a drain region D (the source region S and the drain region D are interchangeable, so they may be collectively referred to as source/drain regions) may be defined by an n-type doping in the active region. A channel region CH may be formed between the source region S and the drain region D. The channel region CH may have substantially a uniform doping (e.g., an unintentional doping, or light doping to adjust a threshold voltage). The nMOSFET has a dual gate configuration. Specifically, a first gate stack G1 may be formed on one side of the channel region CH, and a second gate stack G2 may be formed on the other side of the channel region CH. Generally, the first gate stack G1 and the second gate stack G2 may have the same gate length and be substantially aligned with each other on two opposite sides of the channel region CH. Due to the arrangement, a band gap (indicated by a double-headed arrow in FIG. 23(a)) may become smaller on the drain region D side, and thus electrons are easily tunneled therethrough, resulting in a GIDL.

As shown in FIG. 23(b), in the nMOSFET according to the embodiments of the present disclosure, the channel region CH may have a doping concentration distribution, so that a portion CH low of the channel region close to the drain region D side has a relatively low threshold voltage (e.g., due to the above-mentioned low doping), and an adjacent portion CH high may have a relatively high threshold voltage (e.g., due to the above-mentioned high doping). Due to the difference in threshold voltage, the band gap may be increased with respect to the case shown in FIG. 23(a) on the drain region D side, and it is relatively difficult for electrons to tunnel through, and thus the GIDL may be suppressed.

In this example, a high threshold voltage portion of the channel region may be in a middle portion of the channel region, and a portion of the channel region close to the source region S side may also have a relatively low threshold voltage. Low threshold voltage portions of the channel region respectively close to the source region S and the drain region D may be substantially symmetric with respect to the high threshold voltage portion in the middle portion of the channel region (which may be achieved by an arrangement of the first sublayer 1003a, the second sublayer 1003b and the third sublayer 1003c).

FIG. 23(a) and FIG. 23(b) illustrate a principle of suppressing a GIDL by taking an nMOSFET as an example. The same is true for a pMOSFET. Specifically, in the pMOSFET, a portion of the channel region close to the drain region D side has a relatively high threshold voltage, while an adjacent portion (e.g., a middle portion of the channel region) may have a relatively low threshold voltage.

Although the principle of suppressing a GIDL is illustrated by taking the dual gate configuration as an example, the descriptions are also applicable to a gate-all-around configuration.

In the above-mentioned embodiment, the device has substantially the same or similar configuration on the source region side and the drain region side. However, the present disclosure is not limited to this. From the viewpoint of suppressing a GIDL, the concept of the present disclosure may be applied to the drain region side.

FIG. 24 and FIG. 25 schematically show some stages in a process of manufacturing a MOSFET according to another embodiment of the present disclosure. The differences between the embodiment and the above-mentioned embodiment will be mainly described below.

As shown in FIG. 24, similar to that described above in combination with FIG. 1, a second material layer 1003′ and the third material layer 1005 may be formed on the substrate 1001. Different from the above-mentioned embodiment, the second material layer 1003′ may be divided into a first sublayer 1003a ′ and a second sublayer 1003b ′ which are sequentially stacked in the z direction according to a doping concentration. For example, the second sublayer 1003b ′ may be unintentionally doped or relatively low-doped, while the first sublayer 1003a ′ may be relatively highly doped, e.g., at a doping concentration of about 10¹⁸cm⁻³ to about 10²¹cm⁻³.

After that, the process may be performed according to the above-described embodiment. During an annealing process, a dopant in the second material layer 1003′ may be driven into the first active layer, thereby forming a corresponding doping distribution therein. As shown in FIG. 25, a distribution in which a lower portion (a portion corresponding to the first sublayer 1003a′) of the channel portion is relatively highly doped, while an upper portion (a portion corresponding to the second sublayer 1003b′) of the channel portion is unintentionally doped or relatively low-doped may be formed. In this example, the upper-end source/drain portion may become a drain electrode.

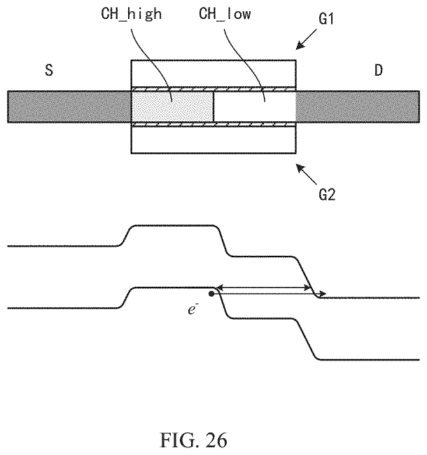

FIG. 26 shows an energy band diagram of an nMOSFET according to the embodiment. As shown in FIG. 26, an increase in the band gap may still be maintained on the drain region D side to suppress benefits of the GIDL.

The MOSFET according to the embodiments of the present disclosure may be applied to various electronic apparatuses. For example, an integrated circuit (IC) may be formed based on the MOSFET, and an electronic apparatus may be constructed therefrom. Accordingly, the present disclosure further provides an electronic apparatus including the above-mentioned MOSFET. The electronic apparatus may also include components such as a display screen cooperating with the integrated circuit and a wireless transceiver cooperating with the integrated circuit, etc. The electronic apparatus includes, for example, a smart phone, a computer, a tablet computer (PC), a wearable smart apparatus, and/or a mobile power supply, etc.

According to the embodiments of the present disclosure, there is further provided a method for manufacturing a System on Chip (SoC). The method may include the above-mentioned methods. In particular, a variety of devices may be integrated on a chip, at least some of which are manufactured according to the method of the present disclosure.

In the above descriptions, technical details such as patterning and etching of each layer have not been described in detail. However, those skilled in the art should understand that various technical means may be used to form layers, regions, etc. of desired shapes. In addition, in order to form the same structure, those skilled in the art may further design a method that is not exactly the same as the method described above. In additional, although the various embodiments have been described above respectively, this does not mean that the measures in the various embodiments may not be advantageously used in combination.

The embodiments of the present disclosure have been described above. However, these examples are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

What is claimed is:

1. A metal oxide semiconductor field effect transistor MOSFET, comprising:
a vertical channel portion on a substrate;
source/drain portions respectively located at upper and lower ends of the channel portion with respect to the substrate; and
a gate stack opposite to the channel portion,
wherein the channel portion has a doping concentration distribution, so that when the MOSFET is an n-type MOSFET, that is, an nMOSFET, a threshold voltage of a first portion of the channel portion close to one of the source/drain portions is lower than a threshold voltage of a second portion adjacent to the first portion; or when the MOSFET is a p-type MOSFET, that is, a pMOSFET, a threshold voltage of a first portion of the channel portion close to one of the source/drain portions is higher than a threshold voltage of a second portion adjacent to the first portion.

2. The MOSFET according to claim 1, wherein the channel portion further comprises a third portion close to the other one of the source/drain portions, and
wherein when the MOSFET is the nMOSFET, a threshold voltage of the third portion is lower than the threshold voltage of the second portion; or when the MOSFET is the pMOSFET, a threshold voltage of the third portion is higher than the threshold voltage of the second portion.

3. The MOSFET according to claim 2, wherein the channel portion exhibits a low-high-low doping concentration distribution in a vertical direction.

4. The MOSFET according to claim 2, wherein a doping concentration in the second portion is in a range of about 10¹⁸ cm⁻³ to about 10²¹ cm⁻³.

5. The MOSFET according to claim 2, wherein the second portion is located at a middle portion of the channel portion in a vertical direction.

6. The MOSFET according to claim 2, wherein the first portion and the third portion of the channel portion are disposed substantially symmetrically with respect to the second portion in a vertical direction.

7. The MOSFET according to claim 1, wherein the second portion of the channel portion is adjacent to the other one of the source/drain portions.

8. The MOSFET according to claim 7, wherein the channel portion exhibits a low-high or high-low doping concentration distribution in a vertical direction.

9. The MOSFET according to claim 8, wherein the high doping concentration is in a range of about 10¹⁸ cm⁻to about 10²⁰ cm⁻³.

10. The MOSFET according to claim 1, wherein the channel portion comprises a curved nanosheet or nanowire having a C-shaped cross section.

11. The MOSFET according to claim 10, wherein the curved nanosheet or nanowire have substantially uniform thickness.

12. The MOSFET according to claim 1, wherein the channel portion contains a single crystal semiconductor material.

13. The MOSFET according to claim 1, wherein the gate stack is self-aligned to the channel portion.

14. The MOSFET according to claim 1, wherein gate lengths of the gate stack are substantially equal on two opposite sides of the channel portion.

15. The MOSFET according to claim 1, wherein the gate stacks are disposed on two opposite sides of the channel portion, or around a periphery of the channel portion.

16. A method for manufacturing a metal oxide semiconductor field effect transistor MOSFET, comprising:
providing a stack of a first material layer, a second material layer and a third material layer on a substrate, wherein the second material layer comprises a first sublayer and a second sublayer that is highly doped with respect to the first sublayer, and the stack has first and second sides opposite to each other in a first direction and third and fourth sides opposite to each other in a second direction intersecting the first direction;
recessing, on the third and fourth sides, a sidewall of the second material layer in the second direction with respect to sidewalls of the first material layer and the third material layer, so as to define a first recessed portion;
forming a first position maintaining layer in the first recessed portion;
recessing, on the first and second sides, the sidewall of the second material layer in the first direction with respect to the sidewalls of the first material layer and the third material layer, so as to define a second recessed portion;
forming a channel layer in the second recessed portion;
forming a second position maintaining layer in the second recessed portion having the channel layer formed;
driving a dopant in the second sublayer into the channel layer in the first direction;
forming source/drain portions in the first material layer and the third material layer;
forming a strip-shaped opening extending in the second direction in the stack, so as to divide the stack into two portions respectively located on the first and second sides;
replacing the second material layer with a third position maintaining layer through the opening;
forming an isolation layer on the substrate, wherein a top surface of the isolation layer is not lower than a top surface of the first material layer and not higher than a bottom surface of the third material layer;
removing the second position maintaining layer and the third position maintaining layer; and
forming a gate stack on the isolation layer, wherein the gate stack has a portion embedded in a space left by a removal of the second position maintaining layer and the third position maintaining layer.

17. The method according to claim 16, wherein the removing the second position maintaining layer and the third position maintaining layer further comprises:
removing the first position maintaining layer,
wherein the gate stack further has a portion embedded in a space left by a removal of the first position maintaining layer.

18. The method according to claim 16, wherein the second material layer further comprises a third sublayer, and the second sublayer is located between the first sublayer and the third sublayer and is highly doped with respect to the first sublayer and the third sublayer.

19. The method according to claim 16, wherein the forming source/drain portions comprises:
forming a dopant source layer on a sidewall of the stack; and
driving a dopant in the dopant source layer into the first material layer and the third material layer,
wherein the dopant in the dopant source layer is driven into the first material layer and the third material layer and the dopant in the second sublayer is driven into the channel layer by a same annealing step;
wherein the forming a channel layer comprises a selective epitaxial growth; and
wherein the recessing a sidewall of the second material layer comprises an isotropic etching.

20. An electronic apparatus comprising the semiconductor device according to claim 1, wherein the electronic apparatus comprises a smart phone, a computer, a tablet computer, a wearable smart apparatus, an artificial intelligence apparatus, or a mobile power supply.
